(19) United States
(12) Patent Application Publication
(10) Pub. No.: US 2026/0247729 A1
(43) Pub. Date: Aug. 20, 2026

(54) SEMICONDUCTOR DEVICE AND PHOTODETECTOR

(71) Applicant: SONY SEMICONDUCTOR SOLUTIONS CORPORATION, Kanagawa (JP)

(72) Inventor: Masaaki BAIRO, Kanagawa (JP)

(73) Assignee: SONY SEMICONDUCTOR SOLUTIONS CORPORATION, Kanagawa (JP)

(21) Appl. No.: 19/164,908

(22) PCT Filed: Feb. 16, 2024
(86) PCT No.: PCT/JP2024/005534

§ 371 Date: Sep. 12, 2025

(30) Foreign Application Priority Data
Mar. 24, 2023 (JP) 2023-048941

(51) Int. Cl. H10F 39/00

(52) U.S. Cl. CPC H10F 39/80373

(57) ABSTRACT

A semiconductor device according to an embodiment of the present disclosure includes: a semiconductor layer; and a capacitor including a first electrode disposed on a side of a first surface of the semiconductor layer, an insulating film stacked on the first electrode, and a first resistor stacked on the insulating film.

### TECHNICAL FIELD

The present disclosure relates to semiconductor devices and photodetectors.

### BACKGROUND ART

A semiconductor integrated circuit with a MOS capacitor overlaid on the gate region of a load MOS transistor has been proposed (Patent Literature 1).

### CITATION LIST

### Patent Literature

Patent Literature 1: Japanese Unexamined Patent Application Publication No. 61-251064

### SUMMARY OF THE INVENTION

Semiconductor devices are required to enhance their performance.

It is desirable to provide semiconductor devices with good performance.

A semiconductor device according to one embodiment of the present disclosure includes a semiconductor layer and a capacitor. The capacitor includes a first electrode disposed on a side of a first surface of the semiconductor layer, an insulating film stacked on the first electrode, and a first resistor stacked on the insulating film.

The photodetector according to one embodiment of the present disclosure includes a photoelectric conversion element that performs photoelectric conversion of light, and a capacitor. The capacitor includes a first electrode disposed on a side of a first surface of a semiconductor layer, an insulating film stacked on the first electrode, and a first resistor stacked on the insulating film.

### BRIEF DESCRIPTION OF THE DRAWINGS

FIG. 1 illustrates an example schematic configuration of an imaging device that is an example of a photodetector according to one embodiment of the present disclosure.

FIG. 2 illustrates an example configuration of the imaging device according to one embodiment of the present disclosure.

FIG. 3A illustrates an example layout of the imaging device according to one embodiment of the present disclosure.

FIG. 3B illustrates an example layout of the imaging device according to one embodiment of the present disclosure.

FIG. 4 explains an example configuration of a pixel in the imaging device according to one embodiment of the present disclosure.

FIG. 5 illustrates an example configuration of the comparison circuit in the imaging device according to one embodiment of the present disclosure.

FIG. 6 illustrates an example layout of the comparison circuit of the imaging device according to one embodiment of the present disclosure.

FIG. 7 explains an example of a cross-sectional configuration of the comparison circuit in an imaging device according to one embodiment of the present disclosure.

FIG. 8A explains another example of a cross-sectional configuration of the comparison circuit in an imaging device according to one embodiment of the present disclosure.

FIG. 8B explains another example of a cross-sectional configuration of the comparison circuit in an imaging device according to one embodiment of the present disclosure.

FIG. 9 explains an example of a cross-sectional configuration of an imaging device according to one embodiment of the present disclosure.

FIG. 10 explains another example of a cross-sectional configuration of the imaging device according to one embodiment of the present disclosure.

FIG. 11A explains a configuration example of an imaging device according to Modification Example 1 of the present disclosure.

FIG. 11B explains a configuration example of an imaging device according to Modification Example 1 of the present disclosure.

FIG. 12 explains a configuration example of an imaging device according to Modification Example 2 of the present disclosure.

FIG. 13 is a diagram illustrating an example of use of the photodetector.

### MODES FOR CARRYING OUT THE INVENTION

The following describes embodiments of the present disclosure in detail with reference to the drawings. Note that the explanation will be given in the following order.
1. Embodiment
2. Modification Examples
3. Examples of use

### 1. Embodiment

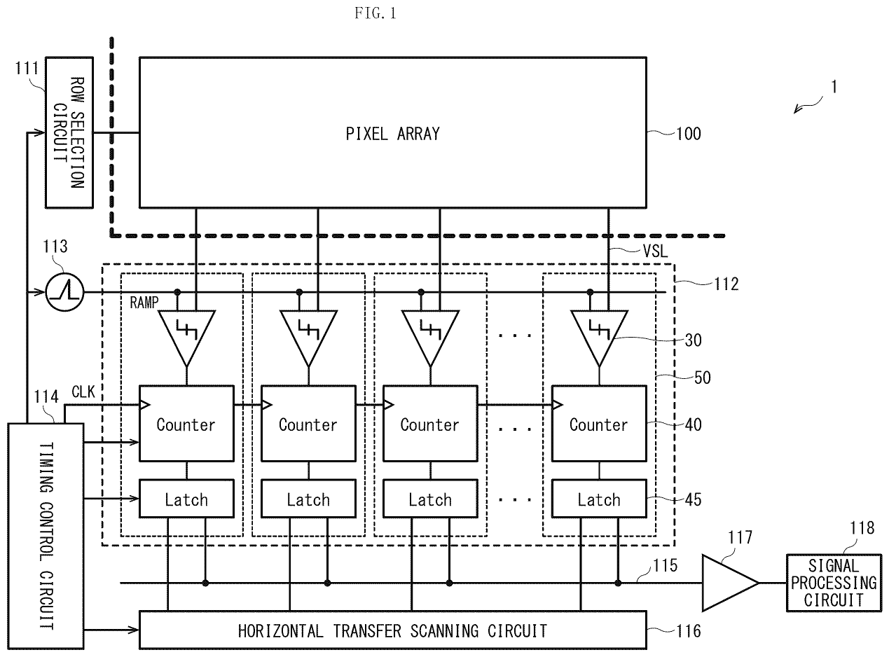

FIG. 1 is a block diagram illustrating an example schematic configuration of an imaging device that is an example of a photodetector according to one embodiment of the present disclosure. A photodetector is a device capable of detecting incident light. The imaging device 1, which is a photodetector, has a plurality of pixels P each having a photoelectric converter (photoelectric conversion element), and is configured to perform photoelectric conversion on incident light to generate a signal. The photodetector 1 is applicable to, for example, an image sensor and a ranging sensor.

The imaging device 1 (photodetector) is capable of receiving light that has passed through an optical system (not illustrated) including an optical lens and generating a signal. The photoelectric converter of each pixel P of the imaging device 1 is, for example, a photodiode (PD) and is configured to be capable of photoelectrically converting light. The imaging device 1 has a region (pixel array 100) as the imaging area, in which a plurality of pixels P is arranged two dimensionally in a matrix. The pixel array 100 is a sensor section (pixel section) in which a plurality of pixels P is arranged, and may also be called a light receiving region.

The imaging device 1 captures incident light (image light) from a subject via an optical system that includes an optical lens. The imaging device 1 captures an image of a subject formed by the optical lens. The imaging device 1 is capable of generating pixel signals by photoelectrically converting the received light.

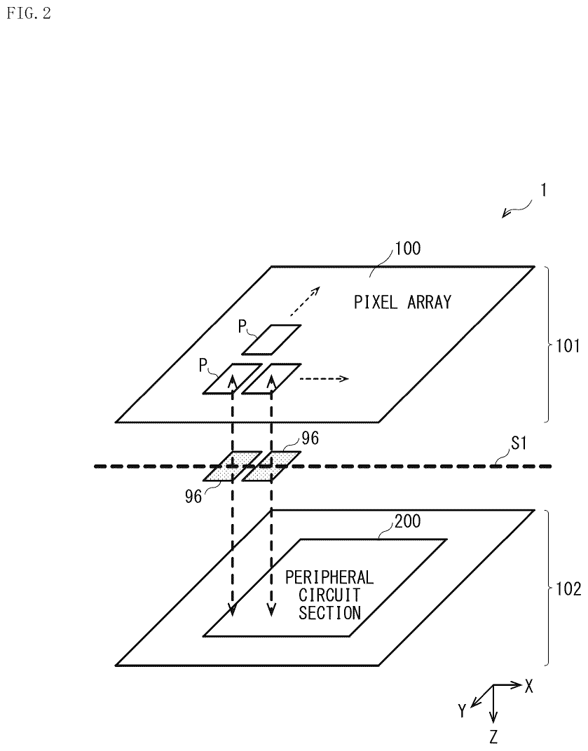

In one example, the imaging device 1 includes the pixel array 100 and a peripheral circuit section 200 capable of reading electrical signals from the pixel array 100 and executing predetermined signal processing (see also FIG. 2). The imaging device 1 is, for example, a complementary metal oxide semiconductor (CMOS) image sensor.

The imaging device 1 is a device capable of receiving incident light and generating a signal, and may also be called a light receiving device. In one example, the imaging device 1 may be used in electronic devices such as digital still cameras, video cameras, and mobile phones.

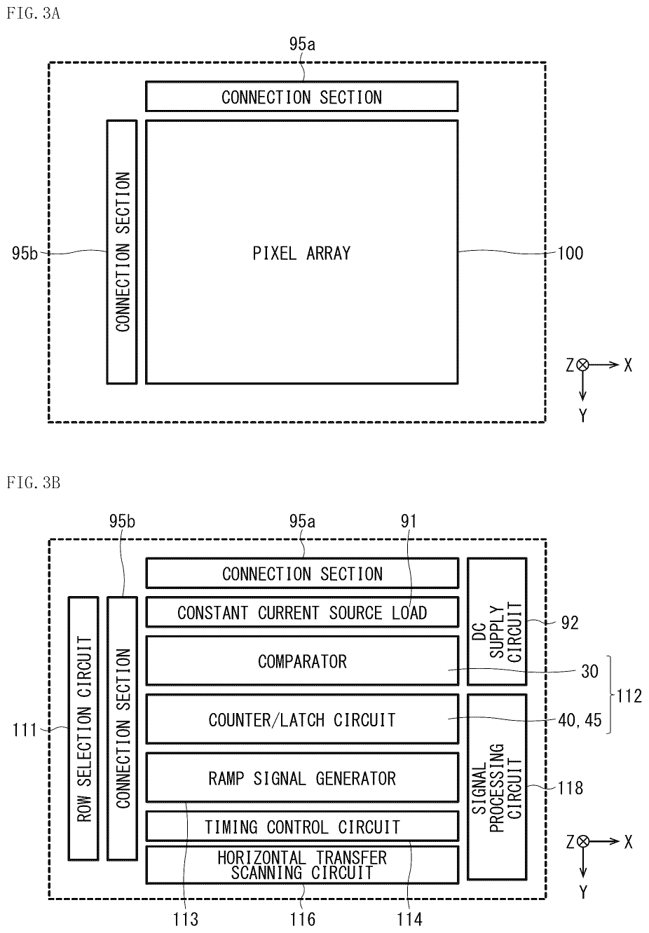

FIG. 2 illustrates an example configuration of an imaging device according to one embodiment. FIG. 3A and FIG. 3B illustrate an example layout of the imaging device. As illustrated in FIG. 2, the imaging device 1 includes a first substrate 101 and a second substrate 102. The first substrate 101 and the second substrate 102 are stacked on top of each other. The first substrate 101 and the second substrate 102 each include a semiconductor substrate (e.g., silicon substrate).

The imaging device 1 has a configuration (a laminated configuration) in which the first substrate 101 and the second substrate 102 are stacked in the Z-axis direction. Note that, as illustrated in FIG. 2, the incident direction of light from the subject to be measured is defined as the Z-axis direction, the left-right direction on the sheet orthogonal to the Z-axis direction is defined as the X-axis direction, and the direction orthogonal to the Z-axis and X-axis directions is defined as the Y-axis direction. In the following drawings, directions may be indicated on the basis of the directions of the arrows in FIG. 2.

On the first substrate 101, the pixel array 100 is provided. In the pixel array 100, a plurality of pixels P is provided in a horizontal direction (row direction) which is a first direction, and a vertical direction (column direction) which is a second direction orthogonal to the first direction. On the second substrate 102, the peripheral circuit section 200 is provided. The peripheral circuit section 200 includes a row selection circuit 111, an ADC group 112, a ramp signal generator 113, a timing control circuit 114, a horizontal transfer scanning circuit 116, an amplifier circuit 117, and a signal processing circuit 118, which are illustrated in FIG. 1, FIG. 3B, and others.

The peripheral circuit section 200 includes semiconductor devices such as MOSFETs, bipolar transistors, resistors, and capacitors formed in the second substrate 102, which are coupled to each other coupled to each other by multi-layer wiring. Note that the peripheral circuit section 200 may be distributed into multiple substrates, e.g., to the first substrate 101 and the second substrate 102. Of the peripheral circuit section 200, the row selection circuit 111, for example, may be provided in the first substrate 101.

As schematically illustrated in FIG. 2, the imaging device 1 is provided with a plurality of electrodes 96. For instance, the electrodes 96 include a metal film such as copper (Cu). The electrodes 96 are used for joining metal electrodes together, and may also be called a joint. In one example, the first substrate 101 and the second substrate 102 are bonded together via a bonding surface S1 by bonding between the plurality of electrodes 96 made of Cu, that is, by Cu—Cu bonding.

The imaging device 1 is configured so that a circuit in the first substrate 101 and a circuit in the second substrate 102 are electrically coupled to each other by the electrodes 96 provided on the bonding surface S1. Connection sections 95a and 95b illustrated in FIG. 3A and FIG. 3B are provided with a plurality of electrodes 96 for bonding. The connection sections 95a and 95b couple the circuit in the first substrate 101 and the circuit in the second substrate 102 to each other. Note that the electrodes 96 may be made of a metal material other than copper, such as nickel (Ni), cobalt (Co), or gold (Au).

The plurality of electrodes 96 at the connection sections 95a and 95b includes an electrode 96 electrically coupling a pixel P to a current source IS1 of a constant current source load 91 via a signal line VSL, an electrode 96 transmitting control signals from the timing control circuit 114, and an electrode 96 supplying voltage from a DC supply circuit 92.

The DC supply circuit 92 is configured to be capable of supplying voltage and current to each component of the imaging device 1. The DC supply circuit 92 may include, for example, a charge pump circuit, and is capable of outputting a stepped-down or stepped-up voltage. The DC supply circuit 92 may also be called a voltage generating circuit (or a power supply circuit) capable of supplying a voltage.

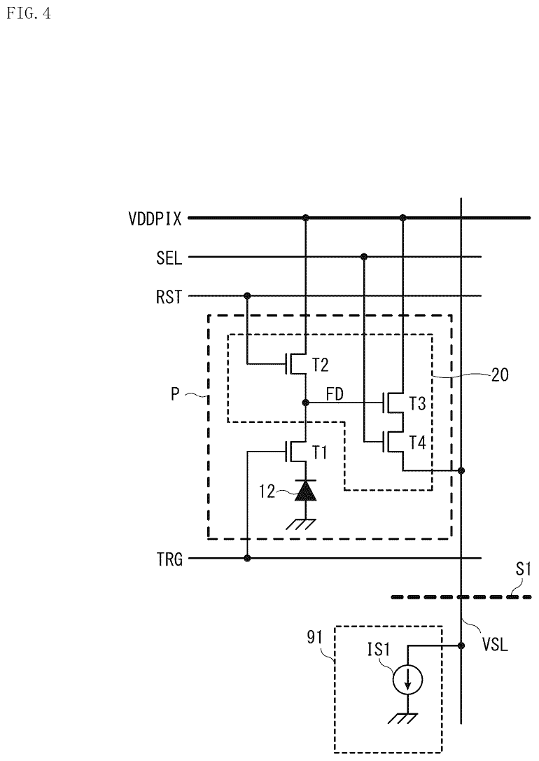

FIG. 4 explains an example configuration of a pixel in the imaging device according to one embodiment. The pixel P includes a photoelectric converter 12 (photoelectric conversion element), a transfer transistor T1, and a readout circuit 20. The photoelectric converter 12 is configured to receive light and generate a signal. The readout circuit 20 is configured to be capable of outputting a signal based on the charge obtained by the photoelectric conversion.

The photoelectric converter 12 is a light receiving unit (light receiving element) and is configured to be capable of generating an electric charge by photoelectric conversion. FIG. 4 illustrates an example, where the photoelectric converter 12 is a photodiode (PD) that converts incident light into an electric charge. The photoelectric converter 12 performs photoelectric conversion to generate an electric charge corresponding to the amount of light received.

In one example, the readout circuit 20 includes a floating diffusion FD, a reset transistor T2, an amplification transistor T3, and a selection transistor T4. These transfer transistor T1, reset transistor T2, amplification transistor T3, and selection transistor T4 are each a MOS transistor (MOSFET) having gate, source, and drain terminals.

In the example illustrated in FIG. 4, the transfer transistor T1, amplification transistor T3, selection transistor T4, and reset transistor T2 each include a NMOS transistor. Note that the transistors in the pixel P may include a PMOS transistor. Note that the readout circuit 20 may include the transfer transistor T1.

The transfer transistor T1 is configured to be capable of transferring the charge photoelectrically converted by the photoelectric converter 12 to the floating diffusion FD. As illustrated in FIG. 4, the transfer transistor T1 is controlled by a signal TRG to electrically couple or decouple the photoelectric converter 12 and the floating diffusion FD to each other or from each other to each other or from each other. The transfer transistor T1 is capable of transferring the charge, which is photoelectrically converted by the photoelectric converter 12 for storage, to the floating diffusion FD.

The floating diffusion FD is a storage and is configured to be capable of storing the transferred charge. The floating diffusion FD is capable of storing the charge photoelectrically converted by the photoelectric converter 12. The floating diffusion FD may also be called a retention unit that is capable of holding the transferred charge. The floating diffusion FD stores the transferred charge and converts it into a voltage according to the capacitance of the floating diffusion FD.

The amplification transistor T3 is configured to generate and output a signal based on the charge stored in the floating diffusion FD. As illustrated in FIG. 4, the gate of the amplification transistor T3 is electrically coupled to the floating diffusion FD, and receives the voltage converted by the floating diffusion FD as an input.

The drain of the amplification transistor T3 is coupled to a power supply line to which a power supply voltage VDDPIX is supplied, and the source of the amplification transistor T3 is coupled to a signal line VSL via the selection transistor T4. The source of the amplification transistor T3 is electrically coupled to the current source IS1 of the constant current source load 91 provided for the signal line VSL.

The constant current source load 91 includes a current source IS1 provided for each signal line VSL, for example. In the pixel array 100, the current source IS1 is provided for each pixel column made up of a plurality of pixels P aligned in the vertical direction (column direction). The current source IS1 is electrically coupled to the signal line VSL.

The current source IS1 is configured to be capable of supplying current to the amplification transistor T3. For instance, the current source IS1, together with the amplification transistor T3, configures a source follower circuit. The amplification transistor T3 is capable of generating a signal based on the charge stored in the floating diffusion FD, that is, a signal based on the voltage of the floating diffusion FD, and outputting it to the signal line VSL.

The selection transistor T4 is configured to be capable of controlling the output of signals from the pixel. The selection transistor T4 is controlled by the signal SEL and is configured to be capable of outputting the signal from the amplification transistor T3 to the signal line VSL.

The selection transistor T4 is capable of controlling the output timing of signals from the pixel. Note that the selection transistor T4 may be located between the power supply line to which the supply voltage VDDPIX is applied and the amplification transistor T3. Furthermore, the selection transistor T4 may be omitted if necessary.

The reset transistor T2 is configured to be capable of resetting the voltage in the floating diffusion FD. FIG. 4 illustrates an example where the reset transistor T2 is electrically coupled to the power supply line to which the power supply voltage VDDPIX is applied and is configured to reset the charge of pixel P.

The reset transistor T2 is controlled by the signal RST and is capable of resetting the charge stored in the floating diffusion FD and thus resetting the voltage of the floating diffusion FD. Note that the reset transistor T2 is capable of discharging the charge stored in the photoelectric converter 12 via the transfer transistor T1.

The row selection circuit 111 (see FIG. 1 and others) supplies control signals to the gates of the transfer transistor T1, reset transistor T2, selection transistor T4, and others of each pixel P, turning the transistors on (conducting state) or off (non-conducting state).

These transfer transistor T1, reset transistor T2, selection transistor T4, and others are on/off controlled by the row selection circuit 111. The row selection circuit 111 controls the transfer transistor T1 and the readout circuit 20 of each pixel P to output a pixel signal from each pixel P to the signal line VSL. The row selection circuit 111 is capable of controlling the reading out of the pixel signal of each pixel P to the signal line VSL.

FIG. 1 illustrates an example where the imaging device 1 includes, as the peripheral circuit section 200, the row selection circuit 111, ADC group 112, ramp signal generator 113, timing control circuit 114, horizontal transfer scanning circuit 116, amplifier circuit 117, and signal processing circuit 118. Furthermore, the imaging device 1 is provided with the plurality of signal lines VSL.

Each signal line VSL is capable of transmitting a signal from the pixel P, and is coupled to the pixel P of the pixel array 100 and the ADC group 112. For instance, the imaging device 1 includes a signal line VSL for each pixel column. The signal line VSL is a vertical signal line and is configured to transmit signals output from the pixel P.

The row selection circuit 111 is a drive circuit, and includes a plurality of circuits including a buffer, a shift register, and an address decoder. The row selection circuit 111 is configured to be capable of driving each pixel P of the pixel array 100. The row selection circuit 111 generates a signal to drive the pixel P and outputs it to each pixel P of the pixel array 100. The row selection circuit 111 is controlled by the timing control circuit 114 to control the pixel P in the pixel array 100.

The row selection circuit 111 generates signals for controlling the pixel P described above, such as a signal for controlling the transfer transistor T1 of the pixel P, a signal for controlling the reset transistor T2, and a signal for controlling the selection transistor T4, and supplies these signals to each pixel P of the pixel array 100. The row selection circuit 111 is capable of controlling to read out a pixel signal from each pixel P.

The ADC group 112 includes a plurality of AD conversion circuits 50, and is capable of outputting the pixel signals converted into digital signals by the AD conversion circuits 50. The AD conversion circuits 50 each include an analog to digital converter (ADC). Each of these AD conversion circuits 50 is provided for a corresponding one of the multiple signal lines VSL. An AD conversion circuit 50 is provided for each pixel column of the pixel array 100.

Each AD conversion circuit 50 is configured to convert an input analog signal into a digital signal. The AD conversion circuit 50 performs AD conversion processing on the pixel signal, which is an analog signal input from each pixel P via the signal line VSL.

The ramp signal generator 113 is configured to be capable of generating a reference signal. The ramp signal generator 113 is a signal generator and is capable of generating a signal whose signal level varies over time. For instance, the ramp signal generator 113 is commonly coupled to the AD conversion circuits 50, generates a reference signal (standard signal) used in AD conversion, and supplies it to each of the AD conversion circuits 50.

For instance, the ramp signal generator 113 includes a digital to analog converter (DAC) and is configured to generate a ramp signal, which is an analog signal, in accordance with a control signal from the timing control circuit 114. FIG. 1 illustrates an example where the ramp signal generator 113 generates the ramp signal RAMP, a reference signal that changes over time on the basis of pulse and clock signals that are output as control signals from the timing control circuit 114.

Each AD conversion circuit 50 includes a comparison circuit 30, a counter 40, and a latch 45. The AD conversion circuit 50 is configured to be capable of converting the input pixel signal into a digital signal with a predetermined number of bits. For instance, the AD conversion circuits 50 each include a single slope ADC.

The comparison circuit 30 includes a comparator, and is configured to be capable of comparing the pixel signal with a reference signal (standard signal). The comparison circuit 30 (comparator) is capable of comparing a pixel signal, which is an analog signal to be converted, with a reference signal to be compared.

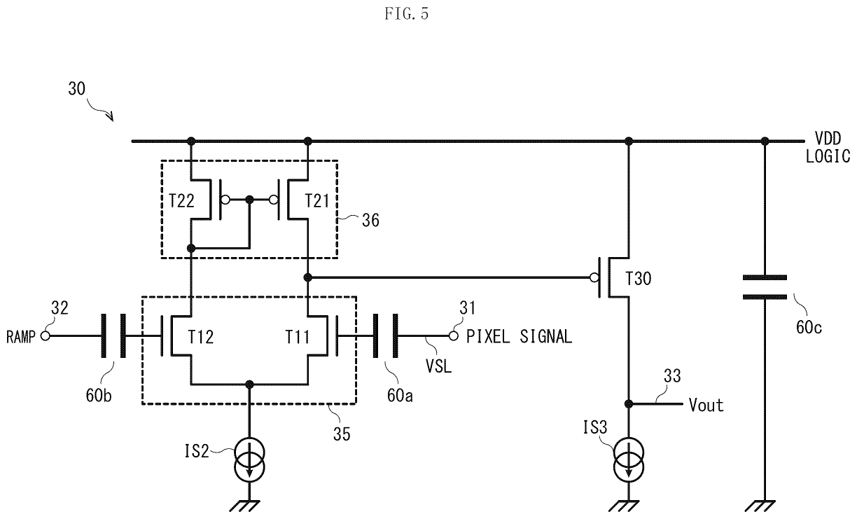

FIG. 5 illustrates an example configuration of the comparison circuit in the imaging device according to one embodiment. For instance, the comparison circuit 30 has an input section 31, an input section 32 and an output section 33, and includes a differential amplifier capable of amplifying a signal. FIG. 5 illustrates an example where the comparison circuit 30 has a differential amplifier including a transistor T11 and a transistor T12 that configure a differential pair 35, and a transistor T21 and a transistor T22 that configure a current mirror 36.

The current mirror 36 and the differential pair 35 are electrically coupled to a location between the power supply line to which a power supply voltage VDDLOGIC is supplied and a ground line (GND line). Note that a capacitor 60c, which is a bypass capacitor, is coupled to a location coupled to a location between the power supply voltage VDDLOGIC and the ground (GND) line.

The transistor T11 and transistor T12 are differential input transistors. For instance, the transistor T11 and the transistor T12 each include an NMOS transistor. The transistor T21 and transistor T22 are active load transistors. For instance, the transistor T21 and the transistor T22 each include a PMOS transistor.

The comparison circuit 30 then includes a transistor T30, a current source IS2, and a current source IS3. The current source IS2 is configured to be capable of supplying current to the different pair 35 and the current mirror 36. The transistor T30 is an output transistor and is electrically coupled to the transistor T11 and the transistor T21. For instance, the transistor T30 includes a PMOS transistor. The current source IS3 is configured to be capable of supplying current to the transistor T30.

The input section 31 of the comparison circuit 30 is a first input terminal and the input section 32 of the comparison circuit 30 is a second input terminal. A capacitor 60a is electrically coupled in series to the input section 31, and a capacitor 60b is electrically coupled in series to the input section 32. The input section 31 receives a pixel signal output from the pixel P to the signal line VSL via the capacitor 60a. Then, the input section 32 receives a ramp signal RAMP from the ramp signal generator 113 via the capacitor 60b.

The comparison circuit 30 compares the signal output from the pixel P with a ramp signal RAMP whose voltage (electric potential) changes, and outputs a signal Vout, which is the comparison result, by the transistor T30. The signal Vout output from the comparison circuit 30 indicates the magnitude relationship between the signal output from the pixel P and the ramp signal RAMP.

The counter 40 illustrated in FIG. 1 is configured to perform counting in response to an input signal. Based on the signal CLK from the timing control circuit 114 and the signal Vout from the comparison circuit 30, the counter 40 (counter circuit) is capable of measuring the time until the comparison result at the comparison circuit 30 is inverted, and outputting a signal indicating the count value to the latch 45 (latch circuit).

The latch 45 is capable of holding a digital signal indicating a count value corresponding to the period from when the comparison circuit 30 starts a comparison until the comparison result is inverted (changed) as a pixel signal after the AD conversion. The pixel signals output sequentially from each pixel P are converted to digital signals by AD conversion by the AD conversion circuit 50.

The horizontal transfer scanning circuit 116 includes a buffer, a shift register, and an address decoder. The horizontal transfer scanning circuit 116 is configured to control the output of pixel signals from the AD conversion circuits 50 in the ADC group 112 to the horizontal transfer line 115. The horizontal transfer scanning circuit 116 is configured to be capable of driving a horizontal selection switch provided for each AD conversion circuit 50, for example.

The horizontal transfer scanning circuit 116 drives each of the horizontal selection switches in turn while scanning them. The pixel signals of each pixel P transmitted through each signal line VSL are converted into digital signals and sequentially output to the horizontal transfer line 115 (horizontal signal line) by selective scanning by the horizontal transfer scanning circuit 116.

The amplifier circuit 117 is configured to be capable of outputting a signal transmitted via the horizontal transfer line 115. The imaging device 1 includes a plurality of horizontal transfer lines 115 and a plurality of amplifier circuits 117 that are correspond to the number of signals (e.g., number of bits) to be transmitted. The amplifier circuit 117 is an output circuit that performs signal processing such as buffering on pixel signals sequentially input from the ADC group 112 via the horizontal transfer lines 115, and is capable of outputting the processed pixel signals to the signal processing circuit 118.

The signal processing circuit 118 is configured to be capable of performing signal processing on the input signal. For instance, the signal processing circuit 118 (signal processor) includes a circuit that performs various types of signal processing on pixel signals. The signal processing circuit 118 may include a processor and a memory. The signal processing circuit 118 performs signal processing on the pixel signals input from the amplifier circuit 117, and outputs the processed pixel signals. The signal processing circuit 118 may perform various types of signal processing, such as noise reduction processing or tone correction processing.

The timing control circuit 114 is configured to be capable of controlling various units of the imaging device 1. The timing control circuit 114 receives an externally given clock, data instructing an operation mode, and others, and is capable of also outputting data such as internal information of the imaging device 1.

For instance, the timing control circuit 114 includes a timing generator configured to be capable of generating various timing signals. The timing control circuit 114 performs drive control of the row selection circuit 111 and the horizontal transfer scanning circuit 116, for example, on the basis of various types of timing signals (e.g., pulse signals and clock signals) generated by the timing generator.

The pixel array 100, the row selection circuit 111, the ADC group 112, the ramp signal generator 113, the timing control circuit 114, the horizontal transfer scanning circuit 116, the amplifier circuit 117, the signal processing circuit 118, and others may be provided separately on multiple semiconductor substrates, or may be provided on a single semiconductor substrate. The pixel array 100 and the peripheral circuit section 200 may be provided on a single substrate.

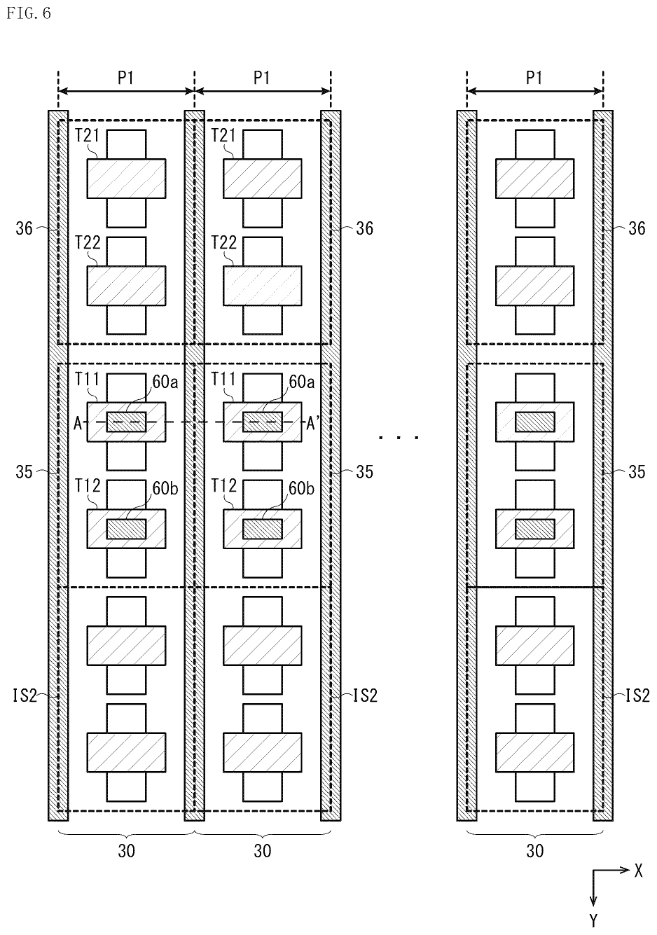

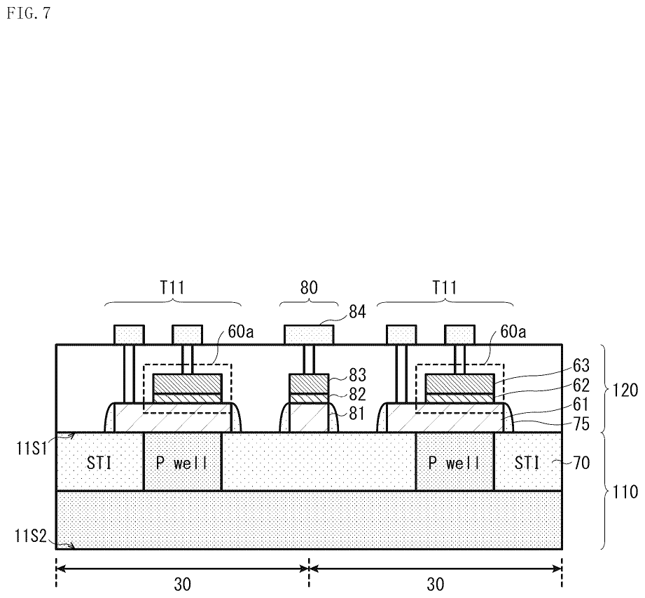

FIG. 6 illustrates an example layout of the comparison circuit of the imaging device according to one embodiment. FIG. 7 then illustrates an example of the cross-sectional configuration of the comparison circuit taken along the A-A′ line in FIG. 6. As illustrated in FIG. 6, the imaging device 1 has a plurality of comparison circuits 30 that are provided side by side with a pitch P1 (placement interval) corresponding to the size of the pixels P. For instance, the smaller the size (or pitch) of the pixels P, the smaller the pitch P1 of the comparison circuits 30.

As illustrated in FIG. 6, each comparison circuit 30 includes the differential pair 35, current mirror 36, current source IS2, and others described above with reference to FIG. 5. The transistors T11 and T12 of the differential pair 35 are each an NMOS transistor. Then, the transistor T21 and the transistor T22 of the current mirror 36 are each a PMOS transistor. FIG. 6 illustrates an example where the current source IS2 includes an NMOS transistor, for example.

As illustrated in FIG. 7, the imaging device 1 has a semiconductor layer 110 and a wiring layer 120. For instance, the semiconductor layer 110 is a substrate that constitutes the imaging device 1, for example, the second substrate 102 described above. The semiconductor layer 110 and the wiring layer 120 are provided with the AD conversion circuits 50, for example, including the comparison circuit 30.

For instance, the semiconductor layer 110 includes a semiconductor substrate, for example, a Si (silicon) substrate. Note that the semiconductor layer 110 may include a silicon on insulator (SOI) substrate, a silicon germanium (SiGe) substrate, or other compound semiconductor materials.

As illustrated in FIG. 7, the semiconductor layer 110 has a first surface 11S1 and a second surface 11S2 that are opposed to each other. The second surface 11S2 is opposite to the first surface 11S1. The first surface 11S1 of the semiconductor layer 110 serves as the device formation surface where transistors and other elements are formed.

On the first surface 11S1 of the semiconductor layer 110, a gate electrode, a gate insulating film (not illustrated), and others are provided. A transistor T11, a transistor T12, a transistor T21, a transistor T22, and others are provided on a side of the first surface 11S1 of the semiconductor layer 110. FIG. 7 illustrates the gate electrode 61 of the transistor T11 and a sidewall 75. The gate electrode 61 of the transistor is provided on the side of the first surface 11S1 of the semiconductor layer 110 via a gate insulating film (not illustrated).

Furthermore, the semiconductor layer 110 has a trench 70. The trench 70 is an isolation portion (groove) and is made of, for example, an insulating material. The trench 70 has a shallow trench isolation (STI) configuration, and is located between the first surface 11S1 and the second surface 11S2 of the semiconductor layer 110. In one example, an insulating film (insulator) such as an oxide film (e.g., silicon oxide film) or a nitride film (e.g., silicon nitride film) is embedded in the trench 70.

The imaging device 1 is provided with the capacitor 60a. The capacitor 60a according to the present embodiment includes an electrode that includes a resistor. For instance, the capacitor 60a is a metal-insulator-metal (MIM) capacitor that includes a resistor (resistive body) as the top electrode. Note that the capacitor 60b may have a similar configuration to the capacitor 60a.
FIG. 7 illustrates an example where the capacitor 60a is stacked on the transistor T11. The capacitor 60a has a resistor 63 as an upper electrode, and an insulating film 62. The capacitor 60a also has the gate electrode 61 of the transistor T11 as a lower electrode. The gate electrode 61 of the transistor T11 doubles as the electrode of the capacitor 60a.

The insulating film 62 is stacked on the gate electrode 61 as the lower electrode. The insulating film 62 is located between the resistor 63 and the gate electrode 61. The insulating film 62 is made of an insulating material such as silicon oxide (SiO) or silicon nitride (SiN).

The insulating film 62 may be made of other dielectric materials having insulating properties. The insulating film 62 may be made of a high dielectric material (e.g., hafnium-based insulating film) having a dielectric constant higher than that of silicon oxide, for example.

The insulating film 62 may include a dielectric film containing a rare earth element. For instance, the insulating film 62 may include at least one element of niobium (Nb), tantalum (Ta), titanium (Ti), zirconium (Zr), hafnium (Hf), and lanthanide (La).

For instance, the resistor 63 is a thin-film resistor, and is made of a metal material. In one example, the resistor 63 is a metal film made of titanium (Ti). The resistor 63 serving as the upper electrode is provided so as to be opposed to the gate electrode 61 serving as the lower electrode with the insulating film 62 interposed therebetween. For instance, the width of the resistor 63 is smaller than the width of the gate electrode 61 in the X-axis direction (or the Y-axis direction) (see FIG. 6, FIG. 7, and others).

The resistor 63 is a resistive element (resistive member) and has a sheet resistance of, for example, 200 ohms/square or more. The resistor 63 may include a metal film having a resistance of 200 ohms/square or more. Note that the sheet resistance value of the resistor 63 may be set appropriately in accordance with the characteristics of the capacitor 60a, for example.

The resistor 63 may include at least one element of titanium (Ti), titanium oxide (TiO), tantalum (Ta), tantalum nitride (TaN), tungsten (W), manganese (Mn), ruthenium (Ru), molybdenum (Mo), cobalt (Co), nickel (Ni), and aluminum (Al).

In one example, the gate electrode 61 includes polysilicon (poly-Si). The gate electrode 61 may include a metal film containing a rare earth element. For instance, the gate electrode 61 may include at least one element of titanium, nickel, zirconium, tantalum, tungsten, aluminum, hafnium, and lanthanoid.

As described above, the imaging device 1 according to the present embodiment includes the capacitor 60a. The capacitor 60a is an MIM capacitance including the electrode that is a resistor. This makes it possible to prevent leakage current from occurring in the capacitor 60a, thereby realizing a high-performance capacitor.

The capacitor 60a is stacked on the transistor T11. Note that the capacitor 60b may have a similar configuration to the capacitor 60a, and may be stacked on the transistor T12 (see FIG. 6). This allows the layout area of the comparison circuit 30 to be reduced. This allows the chip area of the imaging device 1 to be reduced.

The area (e.g., gate length, and gate width) of the transistors T11 and T12 provided in the comparison circuit 30 may be increased, making it possible to suppress random noise from being mixed into the pixel signal. For instance, the number of fingers of the transistors T11 and T12 also may be increased, making it possible to suppress deterioration in quality of the pixel signal. It also makes it possible to suppress deterioration in image quality. This makes it possible to prevent the area of the comparison circuit 30 from increasing and to prevent the random noise from worsening.

Further, the capacitor 60a is stacked on the transistor T11, which makes it possible to reduce the parasitic capacitance added between the capacitor 60a and the transistor T11 to be very small, thereby reducing noise components mixed into the pixel signal. This prevents a large parasitic capacitance from being added by wiring and others, and makes it possible to reduce deterioration of the signal-to-random noise ratio.

Furthermore, in this embodiment, the width of the resistor 63 is smaller than the width of the gate electrode 61, which is the lower electrode, in the X-axis direction (or Y-axis direction), as in the examples illustrated in FIG. 6 and FIG. 7, for example. The capacitor 60a (and capacitor 60b) is provided so that the edge (edge portion) of the upper electrode is positioned inside the edge of the lower electrode. This makes it possible to reduce variations in capacitance caused by misalignment between the upper electrode and the lower electrode. This makes it possible to reduce manufacturing variations in the signal-to-random noise ratio.

Furthermore, the imaging device 1 may have a shield section 80 as in the example illustrated in FIG. 7. For instance, the shield section 80 may have the same configuration as the capacitor 60a (or capacitor 60b). In one example, the shield section 80 has a resistor 83, an insulating film 82, and an electrode 81. The resistor 83 of the shield section 80 corresponds to the resistor 63 of the capacitor 60a and may be made of the same material as the resistor 63.

The insulating film 82 of the shield section 80 corresponds to the insulating film 62 of the capacitor 60a and may be made of the same material as the insulating film 62. The electrode 81 of the shield section 80 may be made of the same material as the gate electrode 61, which is the lower electrode of the capacitor 60a. Note that the shield section 80 may also be referred to as a shielding layer (shielding member).

In the imaging device 1, at least a part of the shield section 80 may be located at the boundary between adjacent comparison circuits 30. FIG. 7 illustrates an example where the shield section 80 is located between adjacent transistors T11.

The imaging device 1 having the shield section 80 is capable of suppressing crosstalk between the multiple comparison circuits 30 adjacent to each other. For instance, it is capable of suppressing noise interference between adjacent transistors T11, thus preventing image quality degradation.

The imaging device 1 may have an electrode 84 electrically coupled to the shield section 80. The electrode 84 is electrically coupled to, for example, wiring, a terminal, and others capable of supplying a predetermined voltage. The resistor 83 of the shield section 80 is electrically coupled via an electrode 84 to a GND line, for example. This makes it possible to suppress crosstalk between circuits due to the shielding effect of the shield section 80, thereby reducing degradation of image quality.

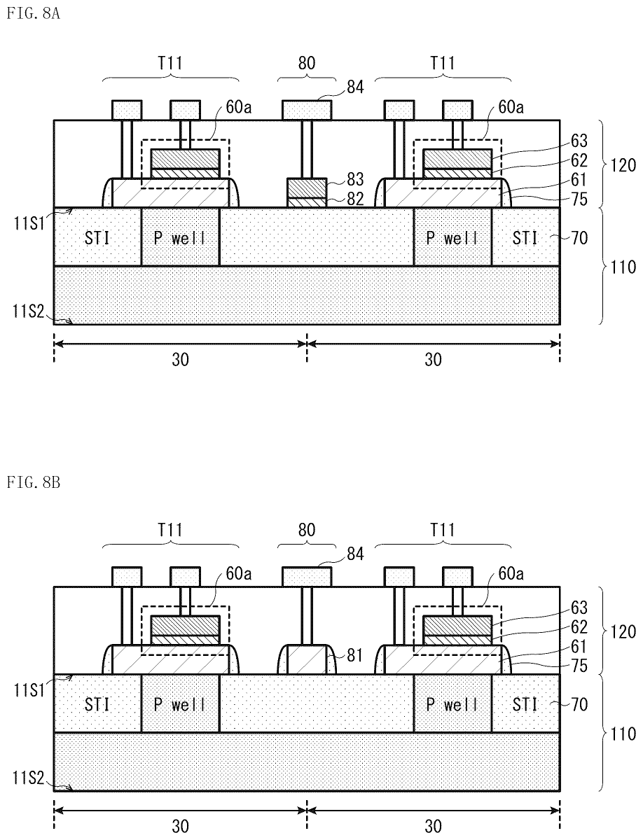

The resistor 83 of the shield section 80 may be supplied with a ground voltage or a power supply voltage as a constant voltage (potential) via the electrode 84. Furthermore, the shield section 80 may have the configuration illustrated in FIG. 8A or FIG. 8B.

For instance, as in the example illustrated in FIG. 8A, the shield section 80 may not have the electrode 81. For instance, as in the example illustrated in FIG. 8B, the shield section 80 may include an electrode 81 and an electrode 84 electrically coupled to the electrode 81.

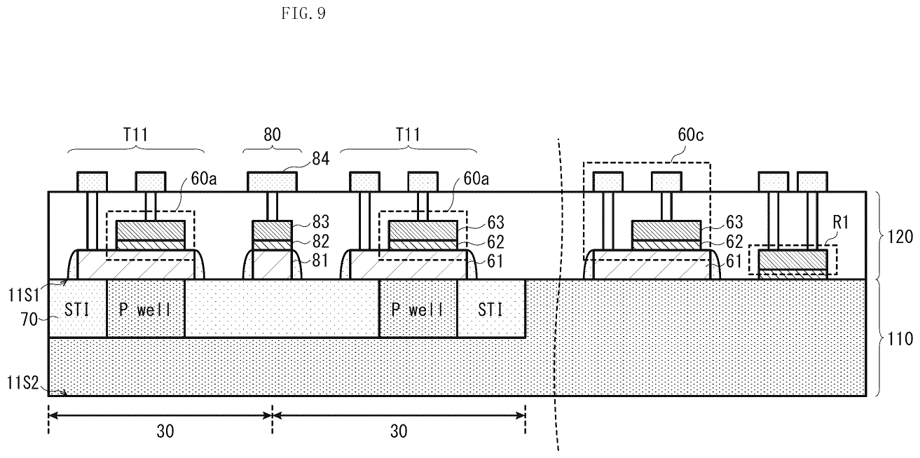

The configuration of elements illustrated in FIG. 7 and others is applicable to other capacitors. For instance, it is applicable to the capacitor 60c of the comparison circuit 30. FIG. 9 explains an example of a cross-sectional configuration of an imaging device according to one embodiment. The capacitor 60c may have a similar configuration to that of the capacitor 60a (or capacitor 60b).

For instance, the capacitor 60c has a resistor 63, an insulating film 62, and a gate electrode 61. As in the example of FIG. 9, the capacitor 60c may be stacked on the transistor. For instance, the capacitor 60c may be stacked on a capacitance (CI capacitance) including an insulating film (e.g., oxide film). The insulating film 62 may be made of a high dielectric constant material (high-k material). This makes it possible to make the capacitance value of the capacitor 60c sufficiently large.

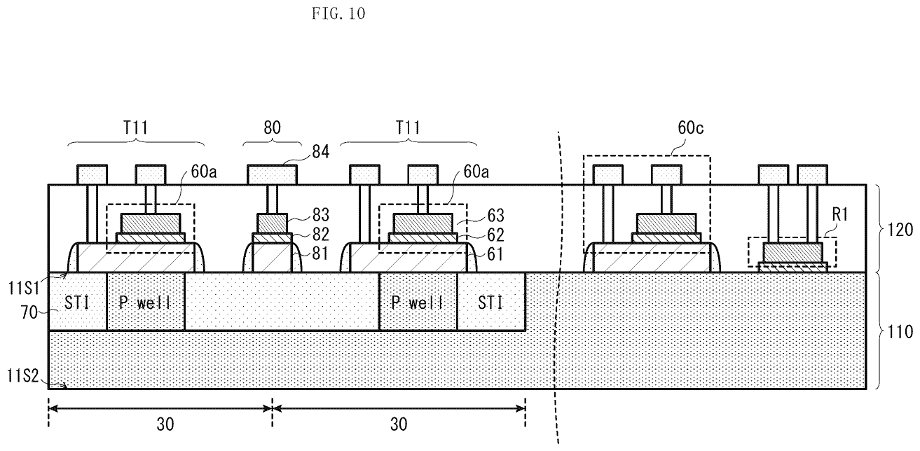

For instance, the width of the resistor 63, the upper electrode, is smaller than the width of the gate electrode 61, the lower electrode. Also, for instance, as in the example in FIG. 10, the width of the resistor 63, the upper electrode, may be smaller than the width of the insulating film 62. This configuration makes it possible to reduce the variations in capacitance value caused by misalignment of the electrode and insulating film (dielectric film).

Furthermore, as in the example in FIG. 9 or FIG. 10, the resistor 63 of the capacitor 60a, the resistor 83 of the shield section 80, the resistor 63 of the capacitor 60c may be made of the same material as the resistor R1 (see FIG. 9 and FIG. 10) provided in other circuits (e.g., the above-mentioned DC supply circuit 92, ramp signal generator 113). This makes it possible to form the top electrode of the capacitor and the resistor included in the semiconductor layer 110 at the same time, thereby reducing the number of processes. This makes it possible to suppress an increase in the manufacturing costs of the imaging device 1.

### [Actions and Advantageous Effects]

The semiconductor device according to this embodiment includes a semiconductor layer (semiconductor layer 110) and a capacitor (e.g., capacitor 60a). The capacitor has a first electrode (e.g., a gate electrode 61) provided close to the first surface of the semiconductor layer, an insulating film (insulating film 62) stacked on the first electrode, and a first resistor (resistor 63) stacked on the insulating film.

The semiconductor device according to the present embodiment is provided with a capacitor 60a having an electrode including a resistor 63. This makes it possible to suppress the leakage current in the capacitor. This enables a semiconductor device with good performance.

Next, the following describes modification examples of the present disclosure. In the following descriptions, like numerals indicate like components of the embodiment as described above, and their descriptions are omitted as needed.

### 2. MODIFICATION EXAMPLES

### 2-1. Modification Example 1

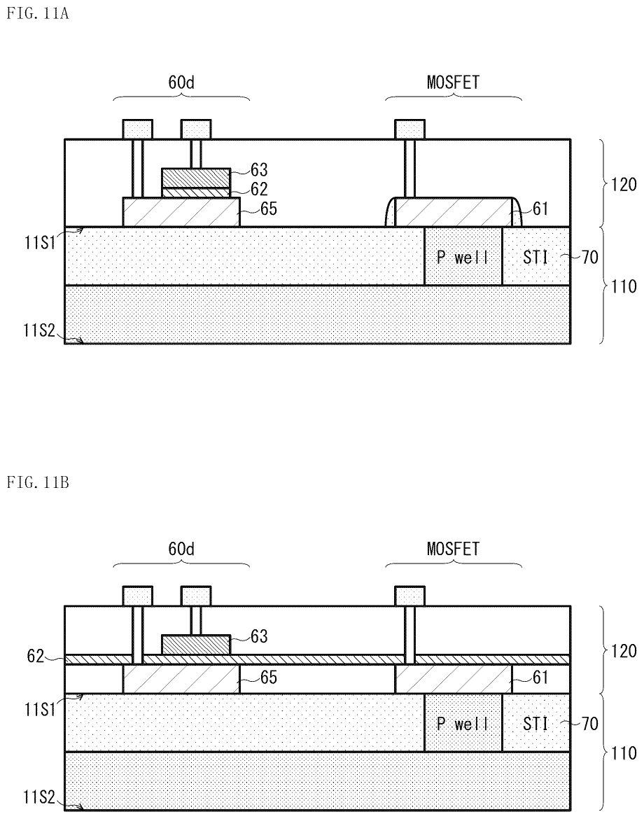

FIG. 11A and FIG. 11B explain a configuration example of an imaging device according to Modification Example 1 of the present disclosure. The above embodiment describes an example where a capacitor is stacked on a transistor. The capacitor may not be stacked on the transistor. As in the example in FIG. 11A, a capacitor (capacitor 60d in FIG. 11A) may be provided separately from a transistor (MOSFET).

For instance, the capacitor 60d has a resistor 63, an insulating film 62, and an electrode 65. For instance, the electrode 65, the lower electrode of the capacitor 60d may be made of the same material as the gate electrode 61 of the transistor. For instance, the capacitor 60d in FIG. 11A or FIG. 11B may be provided as the capacitor 60a or the capacitor 60b described above.

Note that, as in the example in FIG. 11B, the insulating film 62 may not be processed (separated) for each capacitor or transistor. The insulating film 62 may be provided in common to a plurality of elements. FIG. 11B illustrates an example where the insulating film 62 is formed to cover the gate electrode 61 of the transistor and the electrode 65 of the capacitor 60d. This configuration is capable of avoiding edge defects in the insulating film 62, thus making it possible to enhance the reliability of the insulating film 62.

### 2-2. Modification Example 2

The above embodiment describes an example of the configuration of the imaging device 1, which is just an example, and the configuration of the imaging device 1 is not limited to the above example. The transistors provided in the imaging device 1 may be planar transistors or 3D transistors, such as Fin-type transistors (Fin FETs).

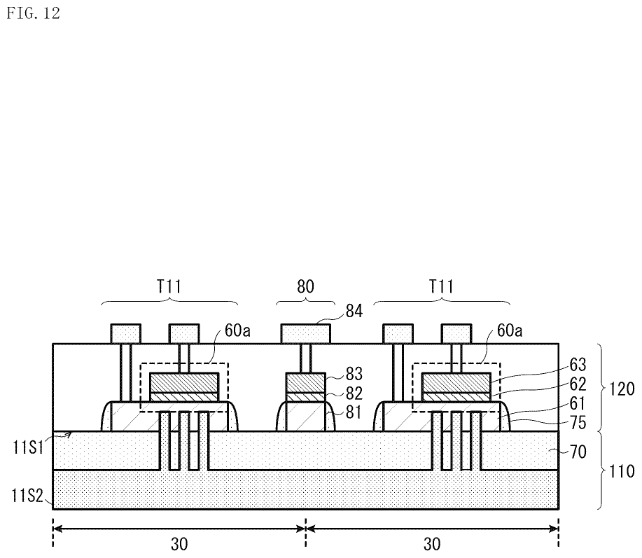

FIG. 12 explains a configuration example of an imaging device according to Modification Example 2. For instance, the transistors (e.g., transistors T11 and T12) in the comparison circuit 30 may be Fin transistors, as in the example schematically illustrated in FIG. 12. This modification example also leads to the same advantageous effects as those described in the above embodiment.

### 2-3. Modification Example 3

The capacitor according to the present disclosure is applicable to various circuits and devices that include capacitors. For instance, the capacitor according to the present disclosure is applicable to various purposes such as a bypass capacitor, a hold capacitor, a filter circuit, a smoothing capacitor, an integrating circuit, and a capacitor type D/A converter circuit. The capacitors according to the present disclosure are applicable to various electronic devices.

### 3. Examples of Use

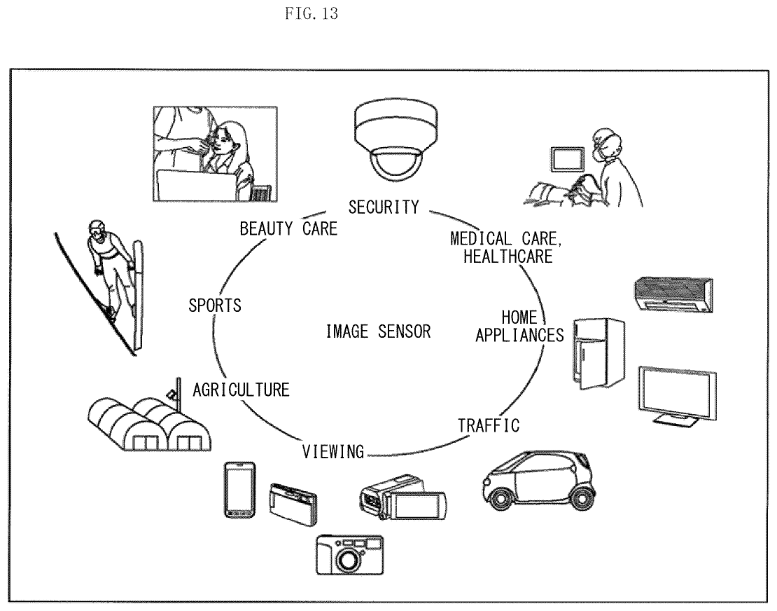

FIG. 13 is a diagram illustrating examples of use of the above-mentioned photodetector. The above-described photodetector (imaging device) may be used in various cases for sensing light such as visible light, infrared light, ultraviolet light, and X-rays as described below:
Digital cameras, mobile devices with camera functions, and other devices that take images for viewing;
Devices used for traffic purposes, such as on-board sensors that take pictures of the front, rear, surroundings, and interior of a vehicle for safe driving such as automatic stopping, and for recognition of the driver's condition, surveillance cameras that monitor moving vehicles and roads, and ranging sensors that measure distances between vehicles;
Devices for use in home appliances such as televisions, refrigerators, and air conditioners to capture user gestures and operate the appliances according to those gestures;
Medical and healthcare devices, such as endoscopes and devices that take blood vessel images by receiving infrared light;
Devices used for security purposes, such as surveillance cameras for crime prevention and cameras for person authentication;
Cosmetic devices such as skin measuring devices that take pictures of the skin and microscopes that take pictures of the scalp;
Devices used for sports, such as action cameras and wearable cameras for sports purposes; and
Agricultural devices such as cameras for monitoring the condition of fields and crops.

While the present disclosure has been described by way of embodiments, modification examples and examples of use, the present technique is not limited to the above embodiments and other examples, and numerous modifications are possible. For instance, although the above-mentioned modification examples each have been described as a modification of the embodiment, the configurations of these modification examples may be combined as appropriate.

The above-described embodiment and other examples describe an imaging device as an example. The photodetector of the present disclosure may be any device that receives incident light and converts the light into an electric charge, for example. The output signal may be an image information signal or a distance measurement information signal. The photodetector (imaging device) is applicable to, for example, an image sensor and a ranging sensor. Furthermore, the semiconductor device (e.g., capacitor) according to the present disclosure is applicable not only to a photodetector but also to various circuits and devices.

The photodetector according to the present disclosure is also applicable as a ranging sensor capable of measuring distance using a time-of-flight (TOF) method. The photodetector (imaging device) is also applicable as a sensor capable of detecting an event, such as an event-driven sensor (called an event vision sensor (EVS), event driven sensor (EDS), dynamic vision sensor (DVS), and others).

The semiconductor device according to one embodiment of the present disclosure includes a semiconductor layer and a capacitor. The capacitor includes a first electrode disposed on a side of a first surface of the semiconductor layer, an insulating film stacked on the first electrode, and a first resistor stacked on the insulating film. This configuration enables a semiconductor device with good performance.

The photodetector according to one embodiment of the present disclosure includes a photoelectric conversion element that performs photoelectric conversion of light, and a capacitor. The capacitor includes a first electrode disposed on a side of a first surface of a semiconductor layer, an insulating film stacked on the first electrode, and a first resistor stacked on the insulating film. This configuration enables a photodetector with good performance.

Note that the advantageous effects described in this specification are just examples and are not limited to the description, and other advantageous effects may also be obtainable. Further, the present disclosure may also have the following configuration.
(1)

A semiconductor device including:
a semiconductor layer; and
a capacitor including a first electrode disposed on a side of a first surface of the semiconductor layer, an insulating film stacked on the first electrode, and a first resistor stacked on the insulating film.
(2)

The semiconductor device according to (1), further including a transistor including a gate electrode disposed on the side of the first surface of the semiconductor layer, in which
the first electrode includes a same material as the gate electrode.
(3)

The semiconductor device according to (1) or (2), further including a transistor disposed on the side of the first surface of the semiconductor layer, in which
the capacitor is stacked on the transistor.
(4)

The semiconductor device according to (3), in which the first electrode includes the gate electrode of the transistor.
(5)

The semiconductor device according to any one of (1) to (4), further including a shield section including a second resistor disposed around the first resistor.
(6)

The semiconductor device according to (5), in which the shield section has a second electrode electrically coupled to the second resistor.
(7)

The semiconductor device according to any one of (1) to (6), in which the first resistor has a width in a direction orthogonal to a stacking direction of the first resistor and the first electrode that is smaller than a width of the first electrode.
(8)

The semiconductor device according to any one of (1) to (7), in which the first resistor has a width in a direction orthogonal to a stacking direction of the first resistor and the insulating film that is smaller than the width of the insulating film.
(9)

The semiconductor device according to any one of (1) to (8), in which the first resistor includes a thin-film resistor.
(10)

The semiconductor device according to any one of (1) to (9), in which the first resistor has a sheet resistance of 200 ohm/sq or more.
(11)

The semiconductor device according to any one of (1) to (10), in which the first resistor includes a metal film of 200 ohms/sq or more.
(12)

The semiconductor device according to any one of (1) to (11), in which the first resistor is opposed to the first electrode.
(13)

A photodetector including: a photoelectric conversion element that performs photoelectric conversion of light; and
a capacitor including a first electrode disposed on a side of a first surface of a semiconductor layer, an insulating film stacked on the first electrode, and a first resistor stacked on the insulating film.
(14)

The photodetector according to (13), further including a transistor disposed on the side of the first surface of the semiconductor layer, in which
the capacitor is stacked on the transistor.
(15)

The photodetector according to (14), in which the first electrode includes a gate electrode of the transistor.
(16)

The photodetector according to any one of (13) to (15), further including an AD conversion circuit that includes the capacitor and that is configured to convert a first signal based on charge photoelectrically converted by the photoelectric conversion element into a digital signal.
(17)

The photodetector according to (16), in which the AD conversion circuit includes a comparison circuit that is configured to compare the first signal input via the capacitor with a reference signal.
(18)

The photodetector according to (17), in which the comparison circuit includes a transistor disposed on the side of the first surface of the semiconductor layer, the transistor receiving the first signal via the capacitor, and
the capacitor is stacked on the transistor.
(19)

The photodetector according to any one of (13) to (18), in which the first resistor includes a metal film of 200 ohms/sq or more.
(20)

The photodetector according to any one of (13) to (19), in which the semiconductor layer has the first surface and a second surface that is opposite to the first surface, and
the semiconductor layer has a trench disposed between the first surface and the second surface.

The present application claims the benefit of Japanese Priority Patent Application JP2023-048941 filed with the Japan Patent Office on March, 24, 2023, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device, comprising:
a semiconductor layer; and
a capacitor including a first electrode disposed on a side of a first surface of the semiconductor layer, an insulating film stacked on the first electrode, and a first resistor stacked on the insulating film.

2. The semiconductor device according to claim 1, further comprising a transistor including a gate electrode disposed on the side of the first surface of the semiconductor layer, wherein
the first electrode includes a same material as the gate electrode.

3. The semiconductor device according to claim 1, further comprising a transistor disposed on the side of the first surface of the semiconductor layer, wherein
the capacitor is stacked on the transistor.

4. The semiconductor device according to claim 3, wherein the first electrode comprises the gate electrode of the transistor.

5. The semiconductor device according to claim 3, further comprising a shield section including a second resistor disposed around the first resistor.

6. The semiconductor device according to claim 5, wherein the shield section has a second electrode electrically coupled to the second resistor.

7. The semiconductor device according to claim 1, wherein the first resistor has a width in a direction orthogonal to a stacking direction of the first resistor and the first electrode that is smaller than a width of the first electrode.

8. The semiconductor device according to claim 1, wherein the first resistor has a width in a direction orthogonal to a stacking direction of the first resistor and the insulating film that is smaller than the width of the insulating film.

9. The semiconductor device according to claim 1, wherein the first resistor comprises a thin-film resistor.

10. The semiconductor device according to claim 1, wherein the first resistor has a sheet resistance of 200 ohm/sq or more.

11. The semiconductor device according to claim 1, wherein the first resistor comprises a metal film of 200 ohms/sq or more.

12. The semiconductor device according to claim 1, wherein the first resistor is opposed to the first electrode.

13. A photodetector, comprising:
a photoelectric conversion element that performs photoelectric conversion of light; and
a capacitor including a first electrode disposed on a side of a first surface of a semiconductor layer, an insulating film stacked on the first electrode, and a first resistor stacked on the insulating film.

14. The photodetector according to claim 13, further comprising a transistor disposed on the side of the first surface of the semiconductor layer, wherein
the capacitor is stacked on the transistor.

15. The photodetector according to claim 14, wherein the first electrode comprises a gate electrode of the transistor.

16. The photodetector according to claim 13, further comprising an AD conversion circuit that includes the capacitor and that is configured to convert a first signal based on charge photoelectrically converted by the photoelectric conversion element into a digital signal.

17. The photodetector according to claim 16, wherein the AD conversion circuit includes a comparison circuit that is configured to compare the first signal input via the capacitor with a reference signal.

18. The photodetector according to claim 17, wherein the comparison circuit includes a transistor disposed on the side of the first surface of the semiconductor layer, the transistor receiving the first signal via the capacitor, and the capacitor is stacked on the transistor.

19. The photodetector according to claim 13, wherein the first resistor comprises a metal film of 200 ohms/sq or more.

20. The photodetector according to claim 13, wherein the semiconductor layer has the first surface and a second surface that is opposite to the first surface, and
the semiconductor layer has a trench disposed between the first surface and the second surface.
